(19) United States
(12) Patent Application Publication
(10) Pub. No.: US 2009/0015276 A1
(43) Pub. Date: Jan. 15, 2009

(54) PROBE ASSEMBLY AND METHOD FOR PRODUCING IT

(75) Inventors: Masatoshi YOKOUCHI, Aomori (JP); Katsushi MIKUNI, Aomori (JP); Masahisa TAZAWA, Aomori (JP); Norihiro IMAI, Aomori (JP)

Correspondence Address: INGRASSIA FISHER & LORENZ, P.C., 7010 E. COCHISE ROAD, SCOTTSDALE, AZ, 85253, US

(73) Assignee: KABUSHIKI KAISHA NIHON MICRONICS, Tokyo (JP)

(21) Appl. No.: 12/147,288

(22) Filed: Jun. 26, 2008

(30) Foreign Application Priority Data
Jul. 11, 2007 (JP) 2007-182383

(51) Int. Cl. B23K 26/20; G01R 1/073

(52) U.S. Cl. 324/754; 219/121.65

(57) ABSTRACT

A method of producing a probe assembly which uses thermal energy of a laser light for bonding a plurality of connection pads provided on a probe board and a probe disposed on each connection pad. In the neighborhood of at least one of the connection pads on the probe board, a dummy connection pad with no probe adhered is formed in order to uniform the thermal energy by irradiation of each bonding portion of each connection pad and the corresponding probe.

### TECHNICAL FIELD

The present invention relates to a probe assembly suitable for conducting a current test of electrical circuits such as integrated circuits formed on a semiconductor wafer and a method for producing it.

### BACKGROUND

Generally, a testing apparatus provided with a tester and a probe assembly with a plurality of probes for connecting the tester to each electrode pad of an integrated circuit which is a device under test is used for an electric test of multiple integrated circuits incorporated into a semiconductor wafer.

In the production of a conventional probe assembly to be assembled into such a testing apparatus, a plurality of probes are adhered by solder to electrically conductive connection pads provided on a probe board. A laser light is used for welding the solder (see, for example, Patent Document 1). When a laser light is used as a heating source of the solder, the probes are arranged to correspond to the connection pads aligned on the probe board, and with solder applied to a bonding portion where the connection pad and the probe are to be bonded, the bonding portion is irradiated with a laser light as an instantaneous laser spot.

The heat to be applied to the bonding portion by the laser light irradiation sometimes adversely affects the bonding quality of the bonding portion and other electronic parts provided on the probe board. In order to prevent such an ill effect and obtain a proper bonding, it is desirable to give minimum required energy to obtain a favorable bonding by melting the solder of the bonding portion. For this reason, a spot diameter of the laser light is set at the width diameter of the electrode pad or less. Also, on the probe board, a plurality of connection pads are aligned, so that, when a certain one connection pad is irradiated with the laser spot, a part of the heat energy is also absorbed by adjoining connection pads disposed adjacent to the probe board. Accordingly, the irradiation energy per shot is set optimally in consideration of a heat loss at each adjoining connection pad.

However, even by the laser irradiation with the energy set as above, by irradiating both outward connection pads located outermost of a connection pad row, a high temperature rise is seen in comparison with the other connection pads aligned between both the outer connection pads. Furthermore, by irradiating the other connection pads isolated from the connection pad rows with the laser light, a further remarkable rise in temperature is seen. It is considered that this is because the other connection pads between both outer connection pads in the connection pad rows, other connection pads to be heat absorption sources adjoin at equal intervals in front and rear in the alignment direction, while to only one of both the outer connection pads the other connection pad is adjacent in the alignment direction, so that dispersion of heat hardly occurs between the other heat absorption sources.

Therefore, in adhering the probes to the connection pads located outermost of such connection pad rows and isolated connection pads, it is desirable to reduce the laser output energy in comparison with a case of adhering to the other connection pads. Thus, in a method of producing a probe assembly which uses the conventional laser light, a need to control the laser light energy according to the arrangement of the connection pads, thereby complicating the structure of a laser irradiation apparatus and causing a rise in the production cost.

As one of techniques to mount a semiconductor chip on a base plate, there is a flip-chip bonding (FCB) technique for bonding an electrode on a base plate and a bump of a semiconductor chip. Further, there is a prior art for bonding them by use of ultrasonic wave pressurized heat to enhance bonding of both by interposing a nonconductive resin between the chip and the mounting base plate (see, e.g., Patent Document 2). In the method according to Patent Document 2, a conductive dummy pattern to be covered by the nonconductive resin is formed on the chip mounting base plate. This dummy pattern aims to temperature distribution of the nonconductive resin covering the conductive dummy pattern uniform by its thermal capacity when an ultrasonic wave is applied. This prevents decrease in reliability of the connection between the base plate and the semiconductor chip due to non-uniform viscosity of the nonconductive resin.

However, the conductive dummy pattern for providing a uniform viscosity to the nonconductive resin when using the ultrasonic wave pressurized heat is, as mentioned above, to aim at making the temperature distribution of the nonconductive resin covering the conductive dummy pattern uniform, and not to aim at uniforming heating of the individual bonding portion of the electrode of the base plate and the bump of the semiconductor chip by the ultrasonic wave pressurized heat.

[Patent Document 1] Japanese Patent Appln. Public Disclosure No. 2002-158264

[Patent Document 2] Japanese Patent Appln. Public Disclosure No. 2006-121115

### BRIEF SUMMARY

An object of the present invention is to provide a method of producing a probe assembly which dispenses with laser energy control according to the alignment of connection pads in a method comprising a step of heating the bonding portion of the connection pad and the probe with thermal energy of a laser light, and which enables to control non-uniform heating caused at the bonding portions of the connection pads in a row of the connection pads or of an isolated connection pad and a probe.

The present invention relates to a method of producing a probe assembly which uses thermal energy of a laser light for bonding a plurality of connection pads provided on a probe board and a probe disposed on each connection pad, and is characterized in that a dummy connection pad with no probe adhered is formed, so as to uniform the thermal energy due to irradiation of the bonding portion of each connection pad and the corresponding probe with the laser light in the neighborhood of at least one of the connection pads on the probe board.

According to the present invention, even it is in the outermost connection pad of a connection pad row or an isolated connection pad that a probe is provided, a dummy connection pad without any probe is provided in a position adjacent to the connection pad. Since this dummy connection pad acts as a heat capacity body, the thermal energy of the laser light applied to the outermost connection pad or the isolated connection pad is effectively dispersed between the connection pad and a neighboring dummy connection pad such as in case of irradiating another connection pad with the laser light. Consequently, without adjusting the energy of the laser light in accordance with the alignment of the connection pads, it is possible to prevent such a great temperature difference as the conventional one from being caused at the bonding portion between the connection pad and the probe to be bonded thereto according to the position of the connection pad in the alignment.

Solder capable of melting by the thermal energy of the laser light can be applied to the bonding portion of the connection pad and the probe.

The plurality of connection pads include a plurality of connection pads aligned at substantially equal intervals to form a connection pad row and connection pads disposed apart and isolated from the connection pad row, and at least one of the dummy connection pads may be formed in the neighborhood of the isolated connection pad.

The isolated connection pad and the dummy connection pad disposed in the neighborhood thereof may be disposed on an extension of the connection pad row.

When the isolated connection pad is disposed on an extension of the connection pad row, the dummy connection pad may be disposed on each side of the extension of the connection pad row.

The plural connection pads are aligned at approximately equal intervals, and the dummy connection pad may be formed to adjoin at least one of both outermost connection pads in the alignment direction of the connection pad row.

The dummy connection pad may be disposed more outward of the connection pad row than the outermost connection pad on the extension of the connection pad row.

The dummy connection pad may be disposed on each side of the extension of the connection pad row.

The probe assembly according to the present invention is one using thermal energy of a laser light for bonding a plurality of connection pads on a probe board and a probe disposed on each of the connection pad, and is characterized by forming a dummy connection pad where no probe is adhered, so as to uniform the thermal energy by irradiating each bonding portion of the connection pad and the probe corresponding to it in the neighborhood of at least one of the connection pads with the probe bonded.

The connection pad and the probe can be bonded through solder which can melt by the thermal energy of the laser light.

The dummy connection pad can be formed in the same planar shape as that of the connection pad where the probe on the probe board is to be bonded.

The dummy connection pad can be formed on the same plane as the plane where the probe on the probe board to be bonded to the connection pad is provided.

The dummy connection pad may be provided in the inside of the probe board.

According to the present invention, as mentioned above, it is possible to effectively control generation of such a large dispersion in temperature rise as in the conventional case at each bonding portion of the connection pads and the probes.

Also, by forming a dummy connection pad with the same thermal capacity as that of the connection pad, it is possible to provide substantially uniform thermal energy to each bonding portion of the connection pads and the probes without adjusting irradiation laser energy in accordance with the alignment of the connection pads. Consequently, a laser irradiation device having a comparatively simple constitution to bond appropriately the connection pads and the probes without adversely affecting the bonding quality of the bonding portions and other electronic parts provided on the probe board, so that a high-quality probe assembly less expensive than the conventional one can be provided.

### BRIEF DESCRIPTION OF THE DRAWINGS

FIG. 1 is a plan view showing part of the probe assembly according to the present invention.

FIG. 2 is a side view of the probe assembly shown in FIG. 1.

FIG. 3 is a sectional view obtained along the line III-III shown in FIG. 1.

FIG. 4 is an explanatory view showing a laser irradiation process according to the present invention.

### DETAILED DESCRIPTION

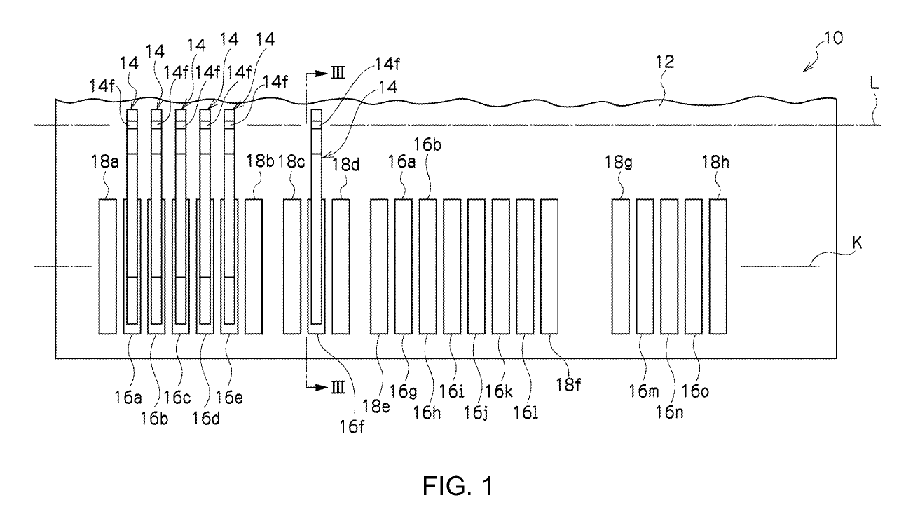

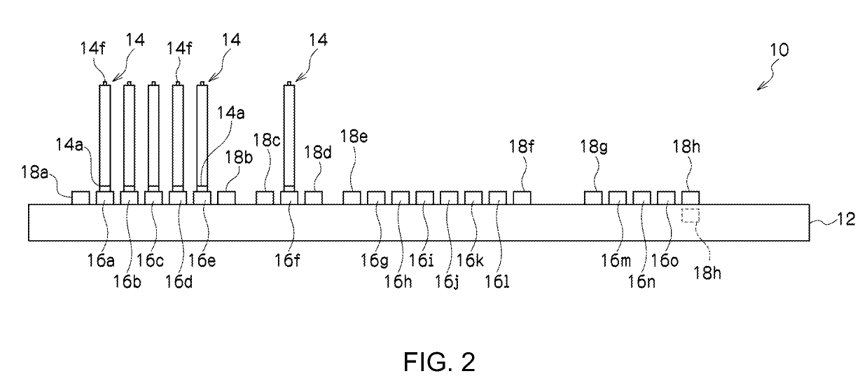

As shown in FIGS. 1 and 2, the probe assembly 10 according to the present invention comprises a probe board 12, and a plurality of probes 14 to be bonded on one face of the probe board. This probe assembly 10 is used for conduction test of plural semiconductor integrated circuits incorporated into, for example, a semiconductor wafer not shown.

Although not shown, the other face of the probe board 12 is provided with a tester land to be connected to an electric circuit of the tester. Also, on the one face of the probe board 12 for the probes 14 to be bonded, connection pads 16 (16a-16o) to each of which the probe 14 is bonded, and a dummy connection pad 18 (18a-18h) without a probe 14 are provided.

Although not shown, the connection pad 16 to which the probe 14 is bonded is connected to the corresponding tester land through a heretofore well-known wiring path provided on the probe board 12. The probe board 12 can be formed from, for example, a laminated structure of a ceramic-like electrically insulated plate where a part of the wiring path is formed, as heretofore known, and a multi-layer wiring board where the remaining part of the wiring path is formed.

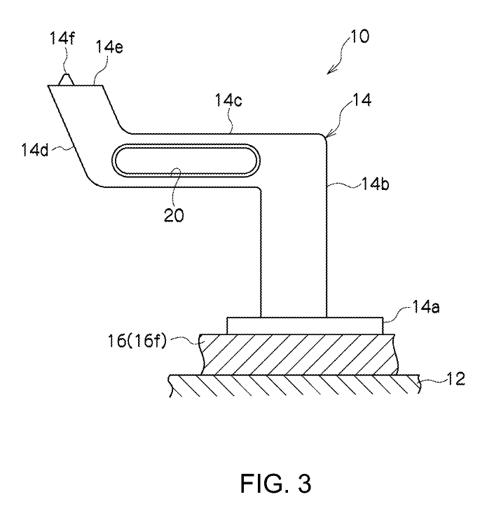

One example of the probe 14 is shown in FIG. 3 as a sectional view along the line III-III shown in FIG. 1. Each probe 14 has, as shown in FIG. 3, an attaching portion 14a as a bonding portion to the connection pad 16, a rising portion 14b on the same plane as that of the attaching portion and rising therefrom, and an arm portion 14c extending from the top of the rising portion substantially horizontally in the lateral direction flush with the plane of both portions 14a and 14b. The arm portion 14c terminates at the front end face 14e through a curving part 14d toward the opposite side of the side where the attaching portion 14a is positioned. In the front end face 14e is formed a tip 14f projecting therefrom.

It is desirable to make the part excluding the tip 14f of the probe 14 of a metal material comparatively rich in toughness such as, for example, nickel, its alloy or phosphor bronze, and to make the tip 14f of a metal material of high hardness in comparison with the part excluding the tip 14f, such as, for example, cobalt, rhodium or their alloys. Also, in the illustration, there is a long hole 20 through the arm portion 14c for promoting flexural deformation of the arm portion 14c in case pressing force acts on the tip 14f toward the probe board 12, but the long hole 20 may be dispensed with.

Each probe 14 is, as shown in FIGS. 1 and 2, bonded to the corresponding pad 16 so that its tip 14f may correspond to each electrode pad formed on the semiconductor wafer. In the example shown in FIG. 1, the electrode pads are aligned on an imaginary line L, and the connection pads 16 are aligned along an imaginary line K parallel to the imaginary line L so that the tips 14f of the probes may be aligned on the imaginary line L.

The connection pads 16, in the illustration, have the same elongated rectangular planar shape and are aligned in the same attitude with their width direction along the extending direction of the imaginary line K such that their longitudinal direction forms right angles to the imaginary line K.

In the example shown in FIG. 1, in the left side part of the figure of the probe board 12, the connection pads 16a to 16e are aligned at equal intervals, for example, of over 10 microns to several dozen microns, toward the right side part of the probe board 12 so as to correspond to the alignment spans of the electrode pads. Thereby, the connection pads 16a to 16e constitute a first connection pad row.

Also, from the first connection pad row (16a to 16e) leftward along an imaginary line K are arranged successively an isolated connection pad 16f, a second connection pad row (16g to 16l) greatly apart from the isolated connection pad 16f, and a third connection pad row (16m to 16o) greatly apart from this connection pad row.

The intervals between the respective connection pads 16g to 16l constituting the second connection pad row correspond to those between the corresponding electrode pads and are equal to the intervals between the respective connection pads 16a to 16e constituting the first connection pad row. The intervals between the respective connection pads 16m to 16o constituting the third connection pad row are likewise equal to those between the connection pads 16a to 16e of the first connection pad row.

Dummy connection pads 18a, 18b are aligned relative to the first connection pads (16a-16e), and dummy connection pads 18c, 18d are disposed relative to the isolated pad 16f. Further, dummy connection pads 18e, 18f are aligned relative to the second pad row (16g-16l), and dummy connection pads 18g, 18h are aligned relative to the third connection pad row (16m to 16o). Each dummy connection pad 18 is of the same material and in the same configuration as those of the connection pad 16, and is formed on the one plane of the probe board 12 where the connection pads 16 are provided.

Both dummy connection pads 18a, 18b relative to the first connection pad row (16a to 16e) are aligned on the imaginary line K so that the connection pad row (16a to 16e) constituting the first connection pad row may be located between both dummy connection pads. Therefore, one dummy connection pad 18a is disposed proximate to one connection pad 16a of both outermost connection pads 16a, 16e to be disposed outward of the first connection pad row (16a to 16e). Also, the other dummy connection pad 18b is proximate to the other outermost connection pad 16e to be disposed outward of the first connection pad row (16a to 16e). Further, both dummy connection pads 18a, 18b are disposed to align with the connection pads 16a to 16e, and the interval between each of the connection pads 16a, 16e and each of the connection pads 16a, 163 proximate to the dummy connection pad is approximately equal to the interval between the respective connection pads 16.

Likewise, relative to the isolated connection pad 16f, the dummy connection pads 18c, 18d are aligned on the imaginary line K with the connection pad f therebetween so that the interval from the connection pad 16f may become equal to that of the respective connection pads 16.

Further, relative to the second connection pad row (16g to 16l), the dummy connection pad 18e is proximate to the one outermost connection pad 16g of the connection pad row on the imaginary line K to be disposed to align outward of the connection pad row. Also, the dummy connection pad 18f is proximate to the other outermost connection pad 16l of the connection pad row (16g to 16l) to be disposed outward of the connection pad row to align with the second connection pad row. The interval between each of the dummy connection pads 18e, 18f and each of the connection pads 16g, 16l proximate to the dummy connection pads is approximately equal to each of the connection pads 16.

Also, regarding the dummy connection pads 18g, 18h relative to the third connection pad row (16m to 16o), as in the first and the second connection pad rows, both dummy connection pads 18g, 18h are aligned on the imaginary line K with the third connection pad row (16m to 16o) therebetween such that the interval between the connection pads 16m and 16o approximately coincides with that of each of the connection pads 16.

Accordingly, in the illustration, the first to the third connection pad rows and the isolated connection pad 16f are aligned on a common extension of the imaginary line K. Also, except the intervals between the adjoining dummy connection pads (18b and 18c, 18d and 18e, and 18f and 18g), the respective connection pads 16 and the respective dummy connection pads 18 are aligned so that the intervals between the respective adjoining connection pads 16 and 18 may become equal.

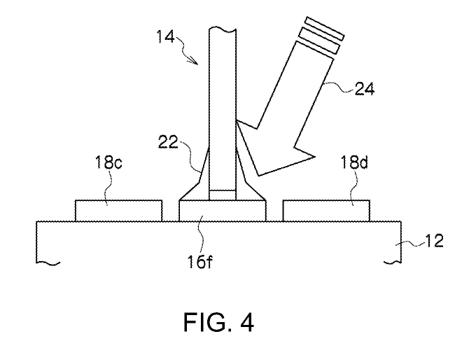

As shown in FIG. 4, the probe 14 is disposed on each connection pad 16 with its attaching portion 14a abutting, each bonding portion of the probe 14 and the connection pad 16 is instantaneously irradiated with a laser irradiation light 24, for example, from one side of the probe 14 in a state that the conventionally well-known solder 22 is applied. The solder 22 can be previously adhered to the attaching portion 14a as heretofore well known.

FIGS. 1 and 2 show a state after the probes 14 are already bonded to the connection pads 16a to 16f but before the probes to be bonded are disposed on the connection pads 16g to 16o.

Referring to FIG. 4 again, for bonding the isolated connection pad 16f and the probe disposed on the connection pad, the bonding portion of the probe 14 and the connection pad 16f is intensively and instantaneously irradiated as mentioned above with the laser irradiation light 24. Thereby, the bonding portion of the probe 14 and connection pad 16f is raised to a temperature sufficient to melt the solder 22 instantaneously, but a part of the thermal energy to be applied to the bonding portion is dispersed into both dummy connection pads 18c, 18d because the adjacent dummy connection pads 18c, 18d act as thermal capacity bodies.

Likewise, when the laser irradiation light 24 is applied for bonding, for example, the connection pad 16a of the first connection pad row (16a to 16e) and the probe 14 disposed on the connection pad, the thermal energy to be applied to the bonding portion is dispersed into the dummy connection pad 18a and the connection pad 16b acting as thermal capacity bodies adjacent to the connection pad 16a. Also, when the laser irradiation light 24 is applied for bonding the connection pad 16b and the probe 14 disposed on the connection pad, the thermal energy to be applied to the bonding portion is likewise dispersed into the connection pad 16a and the connection pad 16c acting as a thermal capacity bodies adjacent to the connection pad 16b.

Thus, by disposing the dummy connection pad 18 relative to each connection pad row (16a-16e, 16g-16l, and 16m-16o) and the isolated pad 16f, it is possible to disperse the thermal energy of the laser irradiation light 24 for bonding the outermost connection pads 16a, 16e, 16g, 16l, 16m, 16o of each row and the isolated connection pad 16f into the adjacent dummy connection pads 18. Accordingly, non-uniform heating according to the connection pad rows caused by the laser irradiation light 24 to the bonding portion of the connection pad 16 and the probe 14 can be controlled.

Also, as mentioned above, by using the dummy connection pad 18 of the same material and the same configuration as that of the connection pad 16, the thermal capacity of the dummy connection pad 18 can be made equal to that of the connection pad 16. Moreover, by aligning the dummy connection pads 18 at equal intervals in the connection pads 16, it is possible to heat the bonding portion between each connection pad 16 and the probe 14 uniformly by the laser irradiation light 24 of the approximately uniform thermal energy without changing the energy of the laser irradiation light 24 according to the alignment positions of the connection pads 16. Therefore, it is possible to bond properly the probe 14 to the connection pad 16 by the laser irradiation light 24 of substantially uniform energy, without adversely affecting the bonding quality of the bonding portion of the connection pad and the probe and other electronic parts provided on the probe board.

An example of forming the dummy connection pad 18 on the plane of the probe board 12 where the connection pads 16 are provided is shown in the foregoing, but the dummy connection pad 18 may be embedded in the probe board 12 like the dummy connection pad 18h representatively shown by an imaginary line in FIG. 2.

Further, in place of disposing on the extension (K) of the pad alignment, the dummy connection pad 18 may be formed on each side in the longitudinal direction of the outermost connection pad or the isolated connection pad so as to make pairs, with the outermost connection pad of each pad alignment or the isolated connection pad interposed.

The present invention is not limited to the above embodiments but can be varied without departing from its purport. For instance, various shapes of contacts may be used as the probes 14, or connection pads 16 and dummy connection pads 18 of various shapes may be adopted.

What is claimed is:

1. A method of producing a probe assembly which uses thermal energy of a laser light for bonding a plurality of connection pads provided on a probe board and a probe to be disposed on each connection pad, characterized by forming a dummy connection pad with no probe adhered in the neighborhood of at least one of the connection pads on the probe board in order to uniform the thermal energy due to the irradiation of each bonding portion of each connection pad and the corresponding probe with the laser light.

2. The method of producing a probe assembly claimed in claim 1, wherein solder capable of melting by the thermal energy of the laser light is applied to the bonding portion of the connection pad and the probe.

3. The method of producing a probe assembly claimed in claim 1, wherein the plurality of connection pads include a plurality of connection pads constituting a row of connection pads aligned at approximately equal intervals, an isolated connection pad apart from the connection pad row, and at least one of the dummy connection pads formed in the neighborhood of the isolated connection pad.

4. The method of producing a probe assembly claimed in claim 3, wherein the isolated connection pad and the dummy connection pad in the neighborhood of the connection pad are disposed on an extension of the connection pad row.

5. The method of producing a probe assembly claimed in claim 3, wherein the isolated connection pad is disposed on an extension of the connection pad row and the dummy connection pad is disposed on each side of the extension of the connection pad row.

6. The method of producing a probe assembly claimed in claim 1, characterized in that the plurality of connection pads are aligned at approximately equal intervals, and that the dummy connection pad is formed adjacent to at least one of both outermost connection pads in the alignment direction of the connection pad row.

7. The method of producing a probe assembly claimed in claim 6, wherein the dummy connection pad is disposed more outward of the connection pad row than the outermost connection pad on the extension of the connection pad row.

8. The method of producing a probe assembly claimed in claim 6, wherein the dummy connection pad is disposed on each side of the extension of the connection pad row.

9. A probe assembly which uses thermal energy of a laser light for bonding a plurality of connection pads provided on a probe board and a probe disposed on each connection pad, wherein a dummy connection pad with no probe adhered is formed in the neighborhood of at least one of the connection pads in order to uniform thermal energy for bonding by irradiation of each connection pad and the corresponding probe with the laser light.

10. The method of producing a probe assembly claimed in claim 9, wherein the connection pad and the probe are bonded through solder capable of melting by the thermal energy of the laser light.

11. The probe assembly claimed in claim 9, wherein the dummy connection pad has the same planar shape as the connection pad to which the probe is bonded on the probe board.

12. The probe assembly claimed in claim 11, wherein the dummy connection pad is formed flush with the plane where the connection pad is provided to which the probe on the probe board is to be bonded.

13. The probe assembly claimed in claim 11, wherein the dummy connection pad is provided in the inside of the probe board.
